(19) United States
(12) Patent Application Publication
(10) Pub. No.: US 2026/0134915 A1
(43) Pub. Date: May 14, 2026

(54) MEMORY CIRCUITS WITH SHARED SELF-TRACKING REFERENCE CIRCUIT AND METHODS FOR OPERATING THE SAME

(71) Applicant: Taiwan Semiconductor Manufacturing Company, Ltd., Hsinchu (TW)

(72) Inventors: Zheng-Jun Lin, New Taipei City (TW); Chung-Cheng Chou, Hsinchu City (TW); Yu-Der Chih, Hsinchu City (TW); Masayoshi Nakayama, Hsinchu City (TW); Atsuo Mangyo, Hsinchu City (TW)

(73) Assignee: Taiwan Semiconductor Manufacturing Company, Ltd., Hsinchu (TW)

(21) Appl. No.: 19/081,563

(22) Filed: Mar. 17, 2025

Related U.S. Application Data
(60) Provisional application No. 63/719,859, filed on Nov. 13, 2024.

(51) Int. Cl. G11C 13/00

(52) U.S. Cl. CPC G11C 13/0064; G11C 13/004; G11C 2013/0054

(57) ABSTRACT

A memory circuit includes a first memory cell and a second memory cell coupled to a first sense amplifier through a first bit line and a second bit line, respectively; a third memory cell and a fourth memory cell coupled to a second sense amplifier through a third bit line and a fourth bit line, respectively; a reference circuit configured to provide a plurality of reference current levels corresponding to different operation modes of any of the first to fourth memory cells, respectively. The reference circuit is alternately coupled to the first bit line and the third bit line or coupled to second bit line and the fourth bit line.

### CROSS-REFERENCE TO RELATED APPLICATION

This application claims priority to and the benefit of U.S. Provisional Application No. 63/719,859, filed Nov. 13, 2024, which is incorporated herein by reference in its entirety for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of a memory circuit, in accordance with some embodiments.

FIG. 2 illustrates a circuit diagram of a memory cell of the memory circuit of FIG. 1, in accordance with some embodiments.

FIG. 3 illustrates a schematic diagram of a portion of the memory circuit of FIG. 1, in accordance with some embodiments.

FIG. 4 illustrates a circuit diagram configured based on the schematic diagram shown in FIG. 3, in accordance with some embodiments.

FIG. 5 illustrates another circuit diagram configured based on the schematic diagram shown in FIG. 3, in accordance with some embodiments.

FIG. 6 illustrates waveforms of signals when operating the memory circuit of FIG. 1, in accordance with some embodiments.

FIGS. 7, 8, 9, and 10 each illustrate an example circuit diagram of a self-tracking reference circuit of the memory circuit of FIG. 1, in accordance with some embodiments.

FIG. 11 illustrates an example circuit diagram of a self-tracking reference circuit of the memory circuit of FIG. 1, in accordance with some embodiments.

FIG. 12 illustrates a plot of ab example relationship between a cell current and a bit count, in accordance with some embodiments.

FIG. 13 is an example flow chart of a method for operating the memory circuit of FIG. 1, in accordance with some embodiments.

FIG. 14 illustrates another schematic diagram of a portion of the memory circuit of FIG. 1, in accordance with some embodiments.

FIG. 15 illustrates a circuit diagram configured based on the schematic diagram shown in FIG. 14, in accordance with some embodiments.

FIG. 16 illustrates an example circuit diagram of a global self-tracking reference circuit of the memory circuit of FIGS. 14-15, in accordance with some embodiments.

FIG. 17 illustrates an example circuit diagram of a local self-tracking reference circuit of the memory circuit of FIGS. 14-15, in accordance with some embodiments.

FIG. 18 illustrates a block diagram of anther memory circuit, in accordance with some embodiments.

FIGS. 19, 20, and 21 illustrate example cross-sectional views of dummy columns for forming a self-tracking reference circuit of the memory circuit of FIG. 1, in accordance with some embodiments.

FIG. 22 illustrates a block diagram of yet anther memory circuit, in accordance with some embodiments.

FIG. 23 and FIG. 24 illustrate example circuit diagrams configured based on the block diagram of FIG. 18, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Many modern day electronic devices include electronic memory devices configured to store data. An electronic memory device is typically a volatile memory device or non-volatile memory device. The volatile memory device stores data when it is powered, while the non-volatile memory device is able to store data when power is removed. A resistive random access memory (RRAM) device is one promising candidate for a next generation non-volatile memory technology. The RRAM device has a simple structure, consumes a small cell area, has a low switching voltage and fast switching times, and is compatible with complementary-metal-oxide-semiconductor (CMOS) fabrication processes.

Memory cells of a RRAM device (typically referred to RRAM cells) can store information based on changes in electric resistance. In general, an RRAM cell includes a bottom electrode, a resistive switching layer, and a top electrode sequentially stacked. The resistance of the resistive switching layer varies according to an applied voltage. An RRAM cell can be in a plurality of states in which the electric resistances are different. Each different state may represent the logic value of a corresponding data bit. The resistance state can be changed by applying a predetermined voltage or current between the electrodes. A resistance state is maintained as long as a predetermined operation is not performed. However, the reliability of a RRAM device is related to its resistance state or filament size. The write/verify process is commonly used to achieve the target resistance states. A (read) sense amplifier can be utilized to perform the verification process and can ensure that a sufficiently large read window is established.

The existing RRAM devices commonly use a constant current source for read/verify operations. However, verifying with a constant current source over a wide temperature range results in over or under writing RRAM cells. For example, once the RRAM cell is over-set or over-reset, endurance of the RRAM cell disadvantageously decreases and the RRAM cell can only be written with less counts. Once the RRAM is weak-set or weak-reset, the RRAM cell's retention is disadvantageously decreased and the RRAM cell data may be lost easily. Thus, the existing RRAM devices have not been entirely satisfactory in certain aspects.

The present disclosure provides various embodiments of an RRAM device (or circuit) that includes a self-tracking reference circuit configured to compensate for IR drops and achieve the target resistance state at different temperatures after write operations. Further, the self-tracking reference circuit, as disclosed herein, can be shared by multiple input/output (I/O) columns of the RRAM circuit, where each of the I/O columns can have at least one corresponding sense amplifier. This can advantageously decrease area penalty induced by the self-tracking reference circuit. For example, through activating a first group of switches and deactivating a second group of switches, the self-tracking reference circuit can be coupled to the first data bit line of a first I/O column and the first data bit line of a second I/O column; and through activating the second group of switches and activating the second group of switches, the self-tracking reference circuit can be coupled to the second data bit line of the first I/O column and the second data bit line of the second I/O column. In various embodiments, the self-tracking reference circuit is configured to provide a process-voltage-temperature (PVT) tracking current level (sometimes just referred to as a reference current). Such a PVT tracking current level can operatively serve as a reference level (I_{ref}) for a corresponding one of plural operation modes (e.g., a normal read operation, a first write verification for checking if a high resistance state has been written to a corresponding RRAM cell, a second write verification for checking if a low resistance state has been written to a corresponding RRAM cell, etc.) of the RRAM circuit.

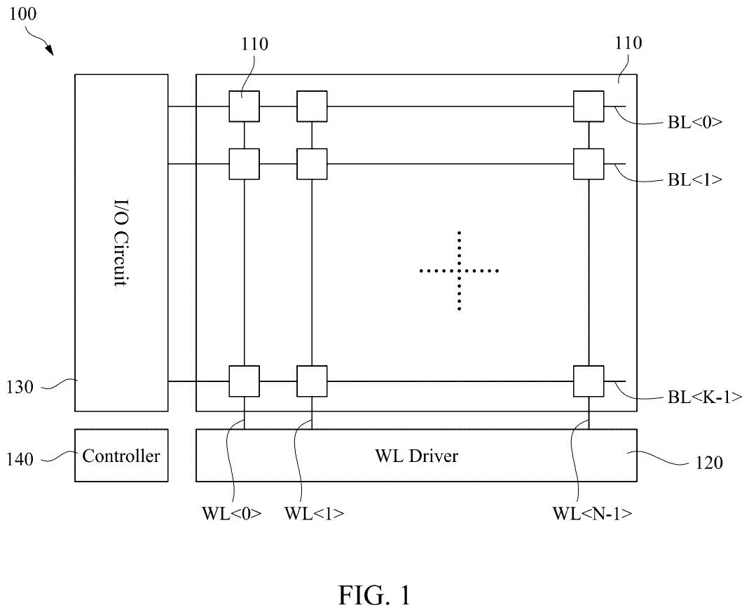

FIG. 1 illustrates an example block diagram of a memory circuit 100, in accordance with various embodiments of the present disclosure. As shown, the memory circuit 100 includes one or more memory arrays 110, a word line (WL) driver 120, and an input/output (I/O) circuit 130, and a memory controller 140. It should be appreciated that the block diagram of FIG. 1 has been simplified for illustrative purposes, and thus, the memory circuit 100 can include any of various other components, e.g., a sinker circuit, a source line (SL) driver, a pre-charge circuit, etc., while remaining within the scope of the present disclosure, in accordance with some embodiments of the present disclosure.

The memory array 110 includes a plurality of storage circuits or memory cells 115, which may be arranged in two-dimensional or three-dimensional arrays. In some embodiments, each of the memory cells 115 includes an RRAM cell configured to store a data bit corresponding to either a high resistance state (high resistance) or a low resistance state (low resistance). However, each of the memory cells 115 can include any of various other configuration of memory cells, while remaining within the scope of the present disclosure. For example, each of the memory cells 115 can include an MRAM cell, a spintronic memory cell, an OTP memory cell, or an SRAM cell.

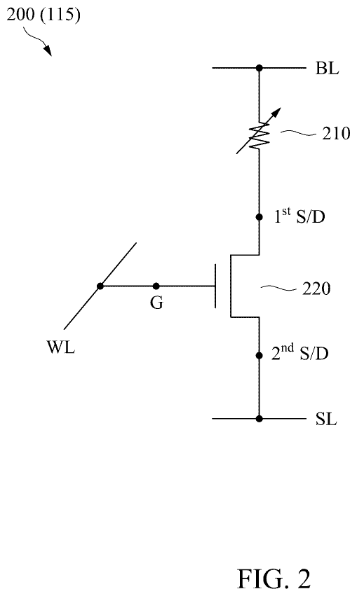

As will be shown below in FIG. 2, each of the memory (RRAM) cells 115 can be implemented as a 1-transistor-1-resistor (1T1R) structure, e.g., a resistor with variable resistance serially connected to a transistor. Each of the memory cells 115 of the memory array 110 may be coupled to a corresponding word line WL and a corresponding bit line BL. For example, each of the memory cells 115 is disposed at the interaction of a corresponding word line WL and a corresponding bit line BL. As shown in the illustrative example of FIG. 1, the memory array 110 includes a number of word lines WLs, e.g., WL<0>, WL<1> . . . WL<N−1>, disposed across multiple array rows, respectively. The number “N” can be any integer. Each of the word lines WLs can extend in a first direction. The memory array 110 further includes a number of bit lines BLs, e.g., BL<0>, BL<1> . . . BL<K−1>, disposed across multiple array columns, respectively. The number “K” can be any integer. Each of the bit lines BLs can extend in a second direction perpendicular to the first direction.

The memory controller 140 is a hardware component that can control (e.g., read) operations of the memory array 110 through the WL controller 120 and/or the I/O circuit 130. The WL driver circuit 120 and the I/O circuit 130 may each be embodied as one or more logic circuits, one or more analog circuits, or a combination of them. In some embodiments, the WL driver circuit 120 is a circuit that can provide a voltage or current (e.g., a WL assertion signal with one or more pulses) through an asserted word line WL of the memory array 110, and the I/O circuit 130 is a circuit that can provide or sense a voltage or current through one or more bit lines BLs of the memory array 110.

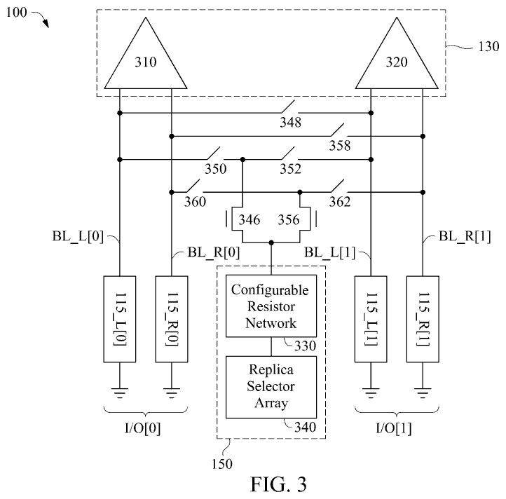

As will be discussed in further detail below (e.g., FIG. 3), the I/O circuit 130 can include a number of sense amplifiers, each of which operatively corresponds to (or is operatively coupled to) a respective subset of the array columns of the memory array 110. In the example illustrated below, the I/O circuit 130 can include a number of I/O columns, each of which includes a respective one of the sense amplifiers and operatively corresponds to a respective pair of the memory columns (of the memory array 110). However, it should be appreciated that each of the sense amplifiers of the I/O circuit 130 can correspond to any other number of the array columns (e.g., through one or more multiplexers), while reaming within the scope of the present disclosure. The I/O circuit 130 can further include a self-tracking reference circuit 150 operatively coupled to a plural number of these I/O columns. Further, in some other embodiments, the memory circuit 100 can include more, fewer, or different components than shown in FIG. 1. For example, the memory circuit 100 can further include a timing controller that can provide control signals or clock signals to synchronize operations of the WL driver circuit 120 and the I/O circuit 130.

For example, a first one of the sense amplifiers can be coupled to a first group of memory cells corresponding to a first I/O column (sometimes referred to as memory cells 115_L[0]) and a second group of memory cells corresponding to the first I/O column (sometimes referred to as 115_R[0]) through a first bit line BL of the first I/O column (sometimes referred to as BL_L[0]) and a second bit line BL of the first I/O column (sometimes referred to as BL_R[0]), respectively. The first group of memory cells can be disposed along a first one of the array columns, and the second group of memory cells can be disposed along a second one of the array columns. A second one of the sense amplifiers can be coupled to a third group of memory cells corresponding to a second I/O column (sometimes referred to as memory cells 115_L[1]) and a fourth group of memory cells corresponding to the second I/O column (sometimes referred to as 115_R[1]) through a first bit line BL of the second I/O column (sometimes referred to as BL_L[1]) and a second bit line BL of the second I/O column (sometimes referred to as BL_R[1]), respectively. The third group of memory cells can be disposed along a third one of the array columns, and the fourth group of memory cells can be disposed along a fourth one of the array columns.

The self-tracking reference circuit 150 can be coupled to the BL_L[0] and BL_L[1], while being decoupled from the BL_R[0] and the BL_R[1]. As such, the self-tracking reference circuit 150 can provide a first PVT tracking current level for the first sense amplifier to compare with a current level present on the BL_R[0], and for the second sense amplifier to compare with a current level present on the BL_R[1]. Similarly, the self-tracking reference circuit 150 can be coupled to the BL_R[0] and BL_R[1], while being decoupled from the BL_L[0] and the BL_L[1]. As such, the self-tracking reference circuit 150 can provide a second PVT tracking current level for the first sense amplifier to compare with a current level present on the BL_L[0], and for the second sense amplifier to compare with a current level present on the BL_L[1].

FIG. 2 illustrates an example circuit diagram of the memory cell 115 of FIG. 1 (hereinafter “memory cell 200”), in accordance with some embodiments of the present disclosure. In FIG. 2, the memory cell 200 includes a selector transistor and a variable resistor connected in series (1T1R), in some embodiments. It, however, should be appreciated that the circuit diagram of FIG. 2 is provided merely for illustrative purpose, and does not intend to limit the scope of the present disclosure.

As shown, the memory cell 200 includes a variable resistor 210 and a selector transistor 220 that are connected in series. The variable resistor 210 can present a resistance state that is switchable or programmable between a low resistance state (LRS) and a high resistance state (HRS). The resistance state can be indicative of a data value (e.g., logic “1” or logic “0”) stored by the memory cell 200. Programming the memory cell 200 into the HRS (e.g., logic 0) is sometimes referred to as performing a RESET operation, and programming the memory cell 200 into the LRS (e.g., logic 1) is sometimes referred to as performing a SET operation. Further, a first terminal of the variable resistor 210 is connected to a bit line BL, a second terminal of the variable resistor 210 is connected to a first source/drain terminal of the selector transistor 220, a gate terminal of the selector transistor 220 is connected to a word line WL, and a second source/drain terminal of the selector transistor 220 is connected to a source line SL which is typically connected to ground. With this configuration, the selector transistor 220 can be activated (e.g., turned on) by asserting the word line WL such as, for example, applying a signal with logic 1 on the gate terminal of the selector transistor 220. Upen being activated, another signal can be applied on the bit line BL to read or write the variable resistor 210.

In some embodiments, the selector transistor 220 can be formed in the front-end-of-line (FEOL) network, while the variable resistor 210 may be formed in the back-end-of-line (BEOL) network. In some other embodiments, both of the selector transistor 220 and the variable resistor 210 can be formed in the back-end-of-line (BEOL) network. Generally, the FEOL network refers to structures formed along the major surface of a semiconductor substrate; and the BEOL network refers to structures formed in metallization layers disposed over the major surface of the semiconductor substrate.

The variable resistor 210 typically includes a resistive switching element/variable resistive dielectric layer sandwiched between a top electrode and a bottom electrode. In some embodiments, the top electrode comprises titanium (Ti) and tantalum nitride (TaN), the bottom electrode comprises titanium nitride (TiN), and the variable resistive dielectric layer comprises nickel oxide (NiO), titanium oxide (TiO), hafnium oxide (HfO), zirconium oxide (ZrO), zinc oxide (ZnO), tungsten oxide (WO₃), aluminum oxide (Al₂O₃), tantalum oxide (TaO), molybdenum oxide (MoO), or copper oxide (CuO), for example. In some embodiments, the bottom electrode can be formed in a lower one of the metallization layers, and the top electrode can be formed in a higher one of the metallization layers. Further, a top electrode via (TEVA) can be formed over the top electrode, and a bottom electrode via (BEVA) can be formed below the bottom electrode, allowing the variable resistor 210 to connect to other structures/components such as, the selector transistor 220, the bit line BL, etc.

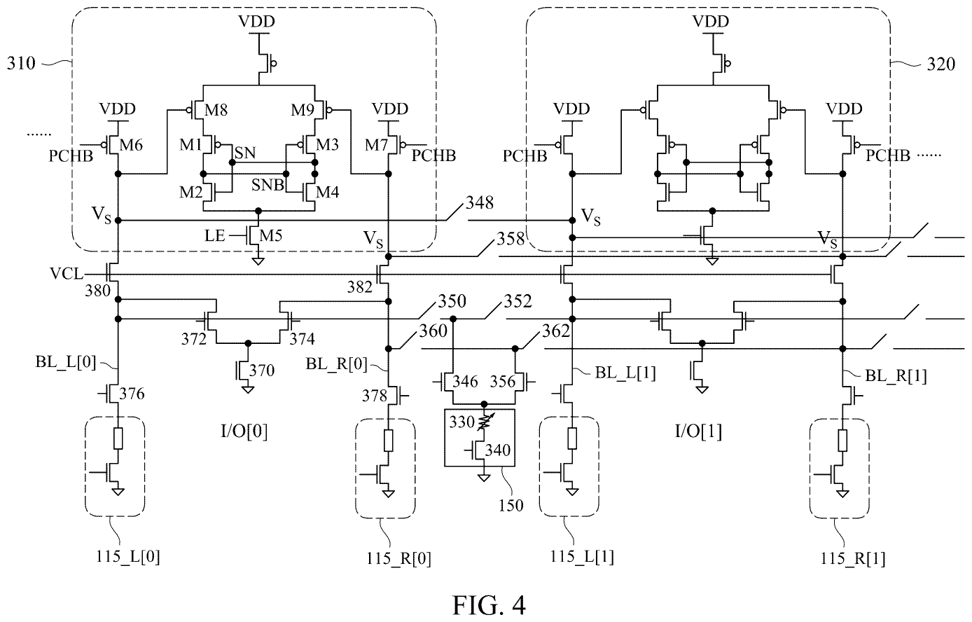

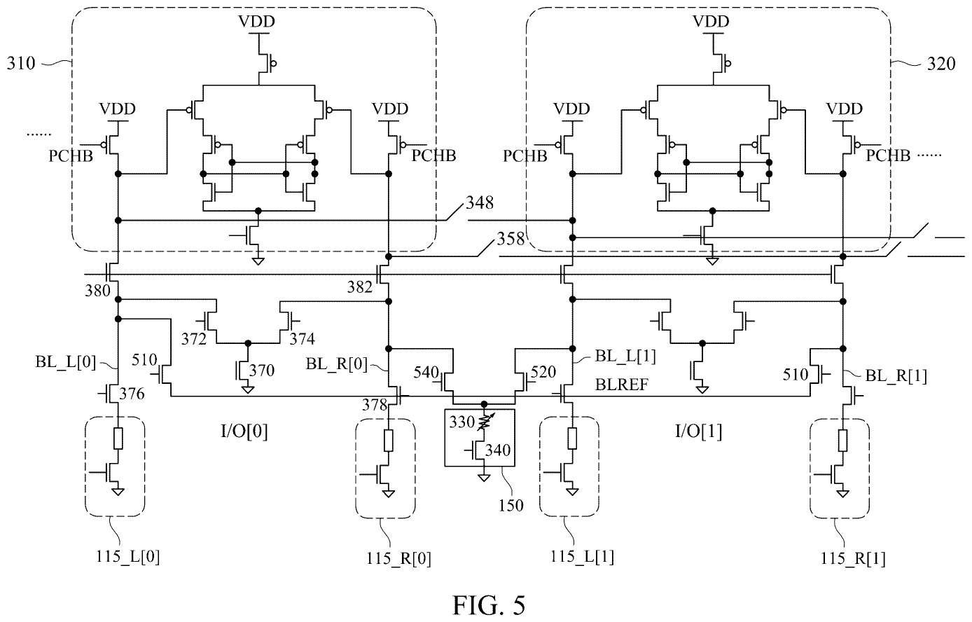

FIG. 3 illustrates an example schematic diagram of a portion of the memory circuit 100 (e.g., two adjacent I/O columns), in accordance with some embodiments of the present disclosure. It should be understood that the schematic diagram of FIG. 3 is provided merely for illustrative purposes, and does not intend to limit the scope of the present disclosure. Thus, the schematic diagram of FIG. 3 can include any of various other components (e.g., as illustrated in FIG. 4 and FIG. 5), while remaining within the scope of the present disclosure.

For example, in the schematic diagram of FIG. 3, the memory circuit 100 includes a first sense amplifier 310 belonging (or coupled) to a first I/O column (e.g., I/O[0]) of the I/O circuit 130, and a second sense amplifier 320 belonging (or coupled) to a second I/O column (e.g., I/O[1]) of the I/O circuit 130. The first sense amplifier 310 is coupled to a first memory cell disposed along a first array column (e.g., 115_L[0]) and a second memory cell disposed along a second array column (e.g., 115_R[0]) through a first bit line of the IO[0](e.g., BL_L[0]) and a second bit line of the I/O[0](e.g., BL_R[0]), respectively. The second sense amplifier 320 is coupled to a third memory cell disposed along a third array column (e.g., 115_L[1]) and a fourth memory cell disposed along a fourth array column (e.g., 115_R[1]) through a first bit line of the I/O[1](e.g., BL_L[1]) and a second bit line of the I/O[1](e.g., BL_R[1]), respectively.

Generally, each of the sense amplifiers of the I/O circuit 130 can include a plural number of transistors, e.g., M1 to M9, where the transistors M1, M3, and M6 to M9 are configured in p-type, and the transistors M2, M4, and M5 are configured in n-type. The transistors M1 and M2 can operatively form a first inverter, and the transistors M3 and M4 can operatively form a second inverter. The first inverter and the second inverter can be cross-coupled with each other. For example, in FIG. 4, gate terminals of the transistors M1 and M2 can be connected to each other at a first internal node (SN) which is further connected to common source/drain terminals of the transistors M3 and M4, and gate terminals of the transistors M3 and M4 can be connected to each other at a second internal node (SNB) which is further connected to common source/drain terminals of the transistors M1 and M2. These cross-coupled inverters can be activated by the transistor M5, which is gated by a control signal (LE). Further, the first inverter can be coupled to BL_L[0] through the transistor M8 which has its gate terminal connected to a first source/drain terminal of the transistor M6; and the second inverter can be coupled to BL_R[0] through the transistor M9 which has its gate terminal connected to a first source/drain terminal of the transistor M7. The transistors M6 and M7 are each gated by another control signal (PCHB), with the first source/drain terminal presenting a signal (VS) and a second source/drain terminal connected to VDD.

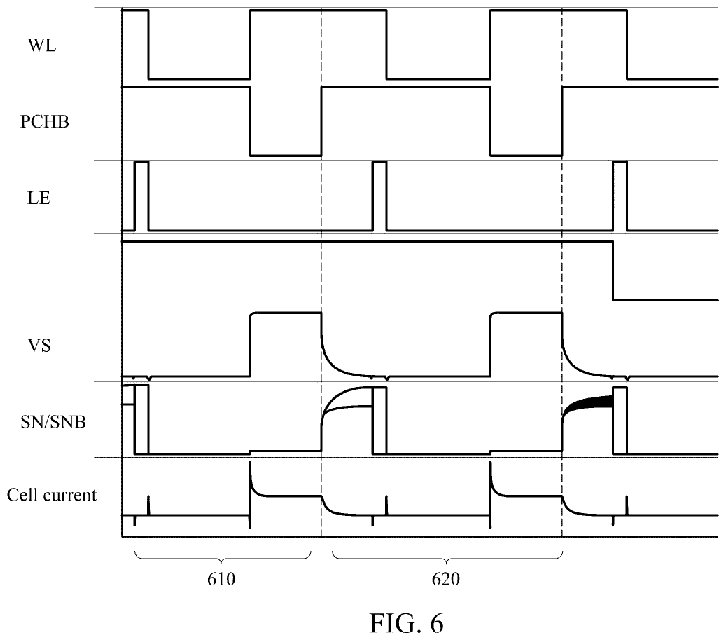

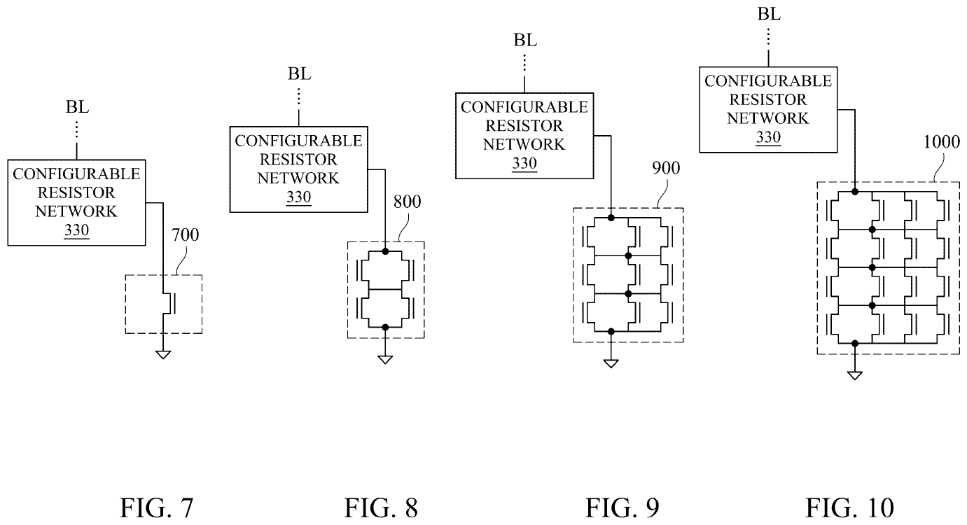

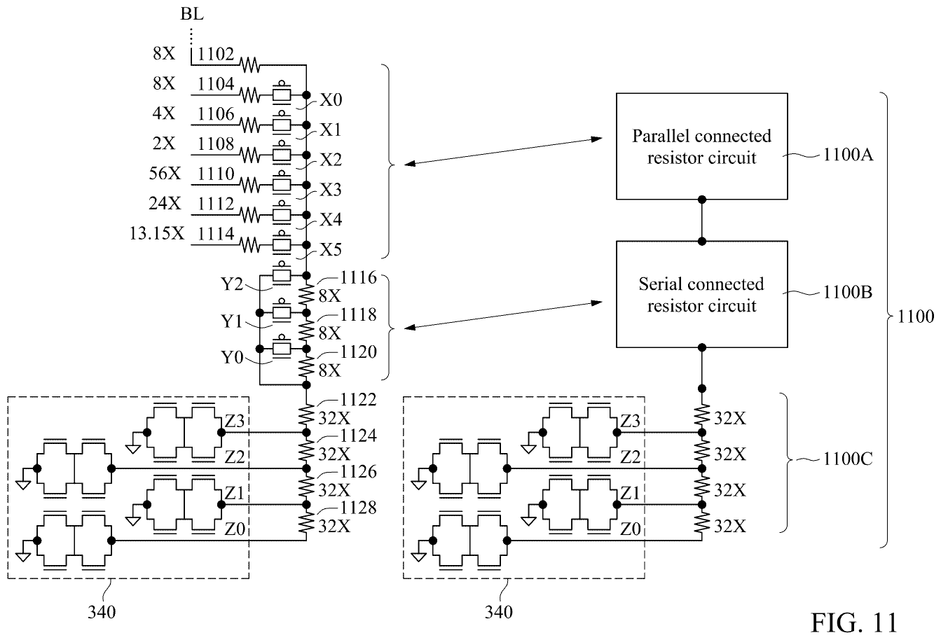

Also illustrated in FIG. 3, the self-tracking reference circuit 150 can include a configurable resistor network 330 and a replica selector array 340 operatively coupled to each other. In some embodiments, the configurable resistor network 330 can emulate the variable resistor of at least one of the memory cell 115_L[0], 115_R[0], 115_L[1], or 115_R[1]. For example, the configurable resistor network 330 can emulate the variable resistor by adjusting one or more of its multiple resistors, such that the overall resistance value of the configurable resistor network 330 matches the resistance value of the selected memory cell configured at a particular operation mode/state. The resistors of the configurable resistor network 330 can be coupled to one another with a series configuration and/or a parallel configuration. With the multiple resistors and/or their different configurations, the self-tracking reference circuit 150 can provide a plural number of PVT-tracking reference current levels, corresponding to different operation modes of the memory cell 115, respectively. The configurable resistor network 330 will be described in further detail in relation to FIG. 11. The replica selector array 340 can emulate the select transistor design of at least one of the memory cell 115_L[0], 115_R[0], 115_L[1], or 115_R[1], and reflect temperature effects to track the cell resistance. The replica selector array 340 can be comprised of serial and/or parallel network of transistors to minimize device process variations. The replica selector array 340 will be described in further detail in relation to FIGS. 7-10.

In some embodiments, the self-tracking reference circuit 150 can be selectively coupled to the BL_L[0] and BL_L[1] through a first group of switches or transistor switches, e.g., 346, 348, 350, and 352; and selectively coupled to the BL_R[0] and BL_R[1] through a second group of switches or transistor switches, e.g., 356, 358, 360, and 362. In other words, the self-tracking reference circuit 150 can be operatively shared by different I/O columns, based on activation/deactivation of those switches 346-352 and 356-362.

When coupled to the BL_L[0] and BL_L[1] by activating the switches 346 to 352, the self-tracking reference circuit 150 can provide a first PVT-tracking reference current level for the sense amplifier 310 to compare a current conducting through the memory cell 115_R[0] with that first PVT-tracking reference current level (thereby identifying a resistance state of the memory cell 115_R[0]), and for the sense amplifier 320 to compare a current conducting through the memory cell 115_R[1] with that first PVT-tracking reference current level (thereby identifying a resistance state of the memory cell 115_R[1]). Alternatively stated, the self-tracking reference circuit 150 can replace one of the inputs of the sense amplifier 310 not selected to be read (e.g., the memory cell 115_L[0]), and/or one of the inputs of the sense amplifier 310 not selected to be read (e.g., the memory cell 115_L[1]), with the first PVT tracking current level.

When coupled to the BL_R[0] and BL_R[1] by activating the switches 346 to 352, the self-tracking reference circuit 150 can provide a second PVT-tracking reference current level for the sense amplifier 310 to compare a current conducting through the memory cell 115_L[0] with that second PVT-tracking reference current level (thereby identifying a resistance state of the memory cell 115_L[0]), and for the sense amplifier 320 to compare a current conducting through the memory cell 115_L[1] with that second PVT-tracking reference current level (thereby identifying a resistance state of the memory cell 115_L[1]). Alternatively stated, the self-tracking reference circuit 150 can replace one of the inputs of the sense amplifier 310 not selected to be read (e.g., the memory cell 115_R[0]), and/or one of the inputs of the sense amplifier 310 not selected to be read (e.g., the memory cell 115_R[1]), with the second PVT tracking current level.

FIG. 4 illustrates an example circuit diagram of a portion of the memory circuit 100, configured based on the schematic diagram of FIG. 3, in accordance with some embodiments of the present disclosure. It should be understood that the circuit diagram of FIG. 4 is provided merely for illustrative purposes, and does not intend to limit the scope of the present disclosure.

In addition to the components shown in FIG. 3, various other transistors, e.g., 370, 372, 374, 376, 378, 380, and 382, are shown in FIG. 4. These transistors 370 to 382 may each function as a switch, and may thus be referred to as a transistor switch. For example, referring again to FIG. 3 and in conjunction with FIG. 4, the sense amplifiers 310 and 320 can each include multiple transistors that are collectively configured to sense a difference between signals present on the coupled pair of bit lines BL, respectively; the memory cells 115_L[0], 115_R[0], 115_L[1], and 115_R[1] each include a variable resistor and a selector transistor connected in series; and the self-tracking reference circuit 150 can include the configurable resistor network 330 and the replica selector array 340. Generally, the I/O columns I/O[0] and I/O[1] may include similar components, and thus, in the following discussion of FIG. 4, the I/O column IO[0] is used as a representative example. For instance, along the BL_L[0], the memory cell 115_L[0] is coupled to the sense amplifier 310 through the transistors 376 and 380; and along the BL_R[0], the memory cell 115_R[0] is coupled to the sense amplifier 310 through the transistors 378 and 382.

The sense amplifier 310, at one time, can operate to compare cell current conducting through the memory cell 115_L[0] with the PVT-tracking reference current level provided by or through the self-tracking reference circuit 150. Alternatively, the sense amplifier 310 can operate to compare cell current conducting through the memory cell 115_R[0] and the PVT-tracking reference current level provided by or through the self-tracking reference circuit 150.

For example, if the sense amplifier 310 is configured to perform a read operation on the memory cell 115_L[0], the sense amplifier 310 can receive a cell current conducting through the memory cell 115_L[0] and the PVT-tracking reference current level provided by the self-tracking reference circuit 150 as its two inputs. As mentioned above, this can happen when the switches/transistor switches 356 to 362 are activated, according to some embodiments. Further, the transistors (sometimes referred to as clamping devices) 380 and 382 are turned on by yet another control signal (VCL) to define a read voltage level, and the transistor 376 is also turned on to enable a cell path to connect the memory cell 115_L[0] to the sense amplifier 310. The cell path can serve as one of the inputs of the sense amplifier 310, or stated another way, can provide a cell current for one of the inputs of the sense amplifier 310. Additionally, a self-tracking reference circuit path can be configured as the other input of the sense amplifier 310 by deactivating the transistors 346 and 378. The self-tracking reference circuit path (sometime referred to as a reference path) is formed for the self-tracking reference circuit 150 to connect to the sense amplifier 310 through the activated transistor switch 356, the switches 362, 360, and 358, and the activated transistor 382. The reference path can serve as the other of the inputs of the sense amplifier 310, or stated another way, can provide a PVT-tracking reference current level for the other input of the sense amplifier 310. Concurrently, a cell path connecting the memory cell 115_R[0] to the sense amplifier 310 is disabled.

For another example, if the sense amplifier 310 is configured to perform a read operation on the memory cell 115_R[0], the sense amplifier 310 can receive a cell current conducting through the memory cell 115_R[0] and the PVT-tracking reference current level provided by the self-tracking reference circuit 150 as its two inputs. As mentioned above, this can happen when the switches/transistor switches 346 to 352 are activated, according to some embodiments. Similarly, the transistors 380 and 382 are turned on by the control signal (VCL), and the transistor 378 is also turned on to enable a cell path to connect the memory cell 115_R[0] to the sense amplifier 310. The cell path can serve as one of the inputs of the sense amplifier 310, or stated another way, can provide a cell current for one of the inputs of the sense amplifier 310. Additionally, a reference path can be configured as the other input of the sense amplifier 310 by deactivating the transistors 356 and 376. The reference path is formed for the self-tracking reference circuit 150 to connect to the sense amplifier 310 through the activated transistor switch 346, the switches 352, 350, and 348, and the activated transistor 380. The reference path can serve as the other of the inputs of the sense amplifier 310, or stated another way, can provide a PVT-tracking reference current level for the other input of the sense amplifier 310. Concurrently, a cell path connecting the memory cell 115_L[0] to the sense amplifier 310 is disabled.

In some embodiments, the transistor 370 may serve as a current source coupled to the BL_L[0] and BL_R[0] through the transistors 372 and 374, respectively. The transistor 370 can generate a small current difference for providing a write verify level to achieve step-by-step boundary trimming. For example, the transistor 370 may serve as a step current generator that can generate a current injected into the above-described self-tracking reference circuit path (or reference path) by controlling the transistor switches 372 and 374. The transistor switch 372, upon being activated, can enable the current injection from the transistor 370 and into the reference path when the memory cell 115_R[0] is selected for being read (e.g., the transistor 376 is deactivated). The transistor switch 374, upon being activated, can enable the current injection from the transistor 370 and into the reference path when the memory cell 115_L[0] is selected for being read (e.g., the transistor 378 is deactivated).

Table I below summarizes activation/deactivation of the above-mentioned switches/transistor switches for the sense amplifier 310 to read the data bits stored by the memory cell 115_L[0] and the memory cell 115_R[0], respectively. In Table I, symbol “O” refers to activation of the corresponding switch/switch transistor, while a blank box refers to deactivation of the corresponding switch/switch transistor. It should be appreciated that the self-tracking reference circuit 150 is operatively shared by multiple I/O columns (e.g., at least IO[0] and IO[1], or their respective sense amplifiers 310 and 320). Thus, the activation/deactivation of the switches/transistor switches that belong to the I/O column IO[0] can apply to activation/deactivation of the switches/transistor switches that belong to the I/O column IO[1], and thus, the description will not be repeated.

TABLE I

| | 346 | 356 | 348 | 350 | 352 | 358 | 360 | 362 | 380 | 382 | 372 | 374 | 376 | 378 |
|---|---|---|---|---|---|---|---|---|---|---|---|---|---|---|
| 115_L[0] | | ◯ | | | | ◯ | ◯ | ◯ | ◯ | ◯ | | ◯ | ◯ | |
| 115_R[0] | ◯ | | ◯ | ◯ | ◯ | | | | ◯ | ◯ | ◯ | | | ◯ |

FIG. 5 illustrates another example circuit diagram of a portion of the memory circuit 100, configured based on the schematic diagram of FIG. 3, in accordance with some embodiments of the present disclosure. The circuit diagram of FIG. 5 is similar to that shown in FIG. 4, and thus, the following discussion will be focused on the difference. It should be understood that the circuit diagram of FIG. 5 is provided merely for illustrative purposes, and does not intend to limit the scope of the present disclosure.

When compared to the circuit diagram of FIG. 4, in FIG. 5, the sense amplifiers 310-320, the self-tracking reference circuit 150, the transistors 370, 372-374, and 380-382 remain, and further, the transistor 348, selectively coupling the BL_L[0] to the BL_L[1], and the transistor 358, selectively coupling the BL_R[0] to the BL_BL_R[1], also remain. However, the transistors 346 and 356, and switches 350-352 and 360-362 may be omitted in FIG. 5. Instead, the circuit diagram of FIG. 5 illustrates transistors 510, 520, 530, and 540, one of the source/drain terminals of each of which is coupled to a reference bit line (BLREF). Specifically, the transistor 510 has the other source/drain terminal connected to the BL_L[0]; the transistor 520 has the other source/drain terminal connected to the BL_L[1]; the transistor 530 has the other source/drain terminal connected to the BL_R[1]; and the transistor 540 has the other source/drain terminal connected to the BL_R[0]. In some embodiments, the transistors 510, 520, 530, and 540 each operatively serve as a part of the reference path (to the self-tracking reference circuit 150). As the transistors 510, 520, 530, and 540 can manufacturing-wise match at least one corresponding transistor along a cell path (e.g., the transistor 510 matching the transistor 376, the transistor 540 matching the transistor 378), process-voltage-temperature (PVT) tracking ability of the self-tracking reference circuit 150 can be further improved.

In some embodiments, the transistors 510-520 may be concurrently activated, with the transistors 530-540 concurrently deactivated. As such, when the transistors 510-520 are activated, the self-tracking reference circuit 150 can provide the first PVT-tracking reference current level for the sense amplifier 310 to compare the current conducting through the memory cell 115_R[0] with that first PVT tracking current level, and for the sense amplifier 320 to compare the current conducting through the memory cell 115_R[1] with that first PVT tracking current level. Similarly, the transistors 530-540 may be concurrently activated, with the transistors 510-520 concurrently deactivated. When the transistors 530-540 are activated, the self-tracking reference circuit 150 can provide the second PVT-tracking reference current level for the sense amplifier 310 to compare the current conducting through the memory cell 115_L[0] with that second PVT tracking current level, and for the sense amplifier 320 to compare the current conducting through the memory cell 115_L[1] with that second PVT tracking current level.

FIG. 6 illustrates respective waveforms of various signals for operating the memory circuit 100 (e.g., the circuit implementation of FIG. 4), in accordance with some embodiments. For example, the WL assertion signal, the PCHB signal, the LE signal, the VS signal, the SN/SNB signal, and the cell current (of FIG. 4) are shown, and thus, the following discussion will sometimes be referred to the components shown in FIG. 4. It should be appreciated that the signals shown in FIG. 6 are provided merely for illustrative purposes, and do not intend to limit the scope of the present disclosure.

As shown, during a first phase 610, different I/O columns (e.g., I/O[0] and I/O[1]) can be concurrently accessed (e.g., read). For example, prior to accessing a memory cell (e.g., 115_L[0] of I/O[0] and/or 115_L[1] of I/O[1]), the PCHB signal can be pulled low to turn on the transistors M6 and M7 and turn off the transistors M8 and M9, so as to pre-charge the BL_L[0] and BL_R[0](and other bit lines) and isolate the first and second inverters formed by the transistors M1 to M4. Next, the WL assertion signal can be pulled high (with the PCHB signal also pulled high) to allow access to the memory cell 115_L[0] and/or 115_L[1]. Once the PCHB signal pulled high, the transistors M6 and M7 are turned off, allowing the SN signal and SNB signal to be developed according to the cell current conducting through the memory cell 115_L[0](or 115_L[1]) and the reference current provided by the self-tracking reference circuit 150, as discussed above. Similarly, during a second phase 620, different I/O columns (e.g., I/O[0] and I/O[1]) can be concurrently accessed (e.g., read), and thus, the discussion will not be repeated.

FIG. 7, FIG. 8, FIG. 9, and FIG. 10 illustrate various example circuit diagrams of the replica selector array 340, respectively, in accordance with some embodiments. Hereinafter, the circuit diagrams of FIGS. 7-10 are referred to as transistor array 700, transistor array 800, transistor array 900, and transistor array 1000, respectively. Each of the transistor arrays 700 to 1000, coupled to the configurable resistor network 330, can track the selector transistors of the memory cells 115. Generally, each of the transistor arrays 700 to 1000 can include one or more transistors coupled to one another, and the transistor arrays 700 to 1000 are configured to equivalently present a common resistance.

In FIG. 7, the transistor array 700 includes a single NMOS transistor. In such a single NMOS transistor configuration, the implemented NMOS transistor can manufacturing-wise match the selector transistors of the memory cells 115. Other types of devices can also be used to implement the single-device replica selector array 340 is also possible. Although the replica selector array 340 can be implemented using a single transistor as illustrated in FIG. 7, increasing the density of the replica selector array 340 can decrease the reference current variations across different PVT. A reference current that includes minimal variations over PVT can provide a verify level to SET/RESET the memory cells 115 to the same resistance.

In FIG. 8, the transistor array 800 includes four NMOS transistors. The four-transistor configuration can be implemented with two sets of two NMOS transistors in a parallel configuration connected in a series configuration. The four-transistor configuration provides a topology that can be represented as: (R//R)+(R//R), wherein the “R” relates to the resistance value associated with each transistor in the four transistor configuration. The resistor value is related to the size of the transistor and can be adjusted by adjusting the resistor sizing. In the disclosed example, the transistors are sized to be the same such that the resistance values for each of the transistors within the four-transistor configuration is also the same.

In FIG. 9, the transistor array 900 includes nine NMOS transistors. The nine-transistor configuration can be implemented using nine transistors connected in series and parallel configurations. The nine-transistor configuration provides a topology that can be represented as: (R//R//R)+(R//R//R)+(R//R//R). Similar to the four-transistor configuration, the nine-transistor configuration also uses “R” to denote the resistance value associated with each transistor in the nine-transistor configuration. In FIG. 10, the transistor array 1000 includes sixteen NMOS transistors. The sixteen-transistor configuration can be implemented using nine transistors connected in series and parallel configurations. The sixteen-transistor configuration provides a topology that can be represented as: (R//R//R//R)+(R//R//R//R)+(R//R//R//R)+(R//R//R//R). Similar to the four-transistor configuration, the sixteen-transistor configuration also uses “R” to denote the resistance value associated with each transistor in the sixteen-transistor configuration.

FIG. 11 illustrates an example circuit diagram of the configurable resistor network 330, in accordance with some embodiments. Hereinafter, the circuit diagram of FIG. 11 is referred to as resistor network 1100. The configurable resistor network 1100 can emulate the variable resistors of the memory cells 115 to provide at least a SET verify level for the PVT tracking current level, a RESET verify level for the PVT tracking current level, or a normal read level for the PVT tracking current level. The configurable resistor network 1100 includes a plurality of trimmable resistors that can be configured to provide a plural number (e.g., 128) of resistance values, which respectively correspond to (e.g., 128) PVT tracking current levels (I_{ref}'s), with minimal PVT variations.

As shown, the configurable resistor network 1100, coupled to the replica selector array 340, includes three parts: 1100A, 1100B, and 1100C. In the illustrative example of FIG. 11, the replica selector array 340 includes a plural number (e.g., 4) of transistor arrays each with a four-transistor configuration (similar to the transistor array 800 of FIG. 8). The first part 1100A includes resistors 1102, 1104, 1106, 1108, 1110, 1112, and 1114, and switches (e.g., each implemented as a transmission gate) X0, X1, X2, X3, X4, and X5; the second part 1100B includes resistors 1116, 1118, and 1120, and switches (e.g., each implemented as a transmission gate) Y2, Y1, and Y0; and the third part 1100C includes resistors 1122, 1124, 1126, and 1128. Sometimes, the resistors 1102-1112 and switches X0-X5 of the first part 1100A are collectively referred to as a parallel connected resistor circuit, and the resistors 1116-1120 and switches Y0-Y2 of the second part 1100B are collectively referred to as a serial connected resistor circuit. In some embodiments, a resistance value of each of the resistors 1102 to 1128 is shown in FIG. 11. By activating/deactivating one or more of the switches X0 to X5, the switches Y0 to Y2, and the nodes Z0 to Z3, the configurable resistor network 1100 can provide a wide range of resistance values.

Table II, Table III, and Table IV below summarize respective activation/deactivation of the above-mentioned switches/nodes for the configurable resistor network 1100 to provide various resistance values. In each of Tables II-IV, symbol “0” refers to activation of the corresponding switch (X0 to X5, Y0 to Y2) or node (Z0 to Z3), while a blank box refers to deactivation of the corresponding switch/node. In some embodiments, the resistance values provided by the configurable resistor network 1100 can build on top of the resistance value of the resistor 1122, sometimes referred to as a DC component of the total resistance value provided by the configurable resistor network 1100. In the illustrative example of FIG. 11, the resistance value of the resistor 1122 is shown as 32×R, where “R” denotes a unit of a resistance value. In Table II-IV, ΔR refers to an increment to 32×R (the resistance value of the resistor 1122), resulting in the total resistance value provided by the configurable resistor network 1100 to be equal to 32×R+ΔR.

Table II illustrates activation/deactivation of the switches X0 to X5; Table III illustrates activation/deactivation of the switches Y0 to Y2; and Table IV illustrates activation/deactivation of the nodes Z0 to Z3. With the configuration shown in FIG. 11, the switches X0 to X5 and the corresponding resistors 1102 to 1114 can provide 8 different values of ΔR, with a resolution of 1×R (Table II); the switches Y0 to Y2 and the corresponding resistors 1116 to 1120 can provide 4 different values of ΔR, with a resolution of 8×R (Table III); and the notes Z0 to Z3 and the corresponding resistors 1122 to 1128 can provide 4 different values of ΔR, with a resolution of 32×R (Table IV).

In the following discussion, some rows of Table II-IV will be selected as representative examples. For example, when the switches X0, X1, and X2 are activated (with the switches Y0 to Y2 also activated to bypass the resistors 1116 to 1120), the resistors 1102 to 1108 can be coupled to one end of the resistor 1122, with the other end of the resistor 1122 coupled to ground through node Z3 being activated. Activated node Z3 may refer to node Z3 coupled to ground through the corresponding transistor array. The resistors 1102 to 1108 are connected to each other in parallel. As such, ΔR is equal to (8R//8R//4R//2R)=R, such that the resistance value provided by the configurable resistor network 1100 is equal to 33×R. In another example, when the switches X0, X1, and X2 are activated (with the switches Y1 and Y0 also activated to bypass the resistors 1118 and 1120) and the switch Y2 is deactivated, the resistors 1102 to 1108 (connected in parallel) and the resistor 1116 can be coupled to one end of the resistor 1122, with the other end of the resistor 1122 coupled to ground through node Z3 being activated. As such, ΔR is equal to (8R//8R//4R//2R)+8R=9R, such that the resistance value provided by the configurable resistor network 1100 is equal to 41×R.

TABLE II

| ΔR | X0 | X1 | X2 | X3 | X4 | X5 |
|---|---|---|---|---|---|---|
| 1X | ◯ | ◯ | ◯ | | | |
| 2X | ◯ | ◯ | | | | |
| 3X | ◯ | | | | | ◯ |
| 4X | ◯ | | | | | |
| 5X | | | | | | ◯ |
| 6X | | | | | ◯ | |
| 7X | | | | ◯ | | |
| 8X | | | | | | |

TABLE III

| ΔR | Y2 | Y1 | Y0 |
|---|---|---|---|
| 24X | | | |
| 16X | | | ◯ |
| 8X | | ◯ | ◯ |
| 0 | ◯ | ◯ | ◯ |

TABLE IV

| ΔR | Z3 | Z2 | Z1 | Z0 |
|---|---|---|---|---|
| 128X | | | | ◯ |
| 96X | | | ◯ | |
| 64X | | ◯ | | |
| 32X | ◯ | | | |

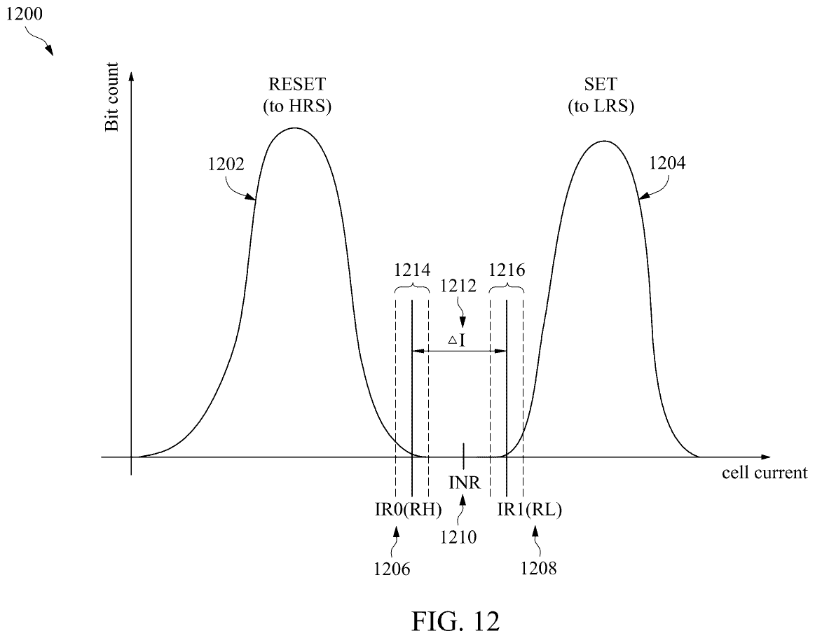

FIG. 12 illustrates a graphical plot 1200 of an example relationship between cell current versus bit count and the effect of a step current injection (e.g., provided by the step current generator 370). In some examples, the X-axis of the graphical plot 1200 illustrates the cell current and the Y-axis of the graphical plot 1200 illustrates the bit count. Curve 1202 represents a cell current during the RESET operation or programmed into the HRS. Curve 1204 represents a cell current during the SET operation or programmed into the LRS. IR0 or RH level 1206 can be the maximum cell current that can still represent the RESET verify level, and IR1 or RL level 1208 can be the minimum cell current that can still represent the SET verify level. The INR level 1210 is the middle resistance value that represents the normal read level. ΔI 512 represents a read window and is the different between the cell current at RH, IR0 1206, and the cell current at RL, IR1 1208.

During the normal operation of an RRAM circuit, an RRAM cell (of the RRAM circuit) can be switched between the HRS and LRS frequently. However, each operation can introduce permanent damage, sometimes referred to as degradation. Endurance or electric fatigue is the number of SET/RESET cycles that can be endured before HRS and LRS are no longer distinguishable. When an RRAM cell is over SET/RESET, the boundary of the RESET and SET curves 1202, 1204 drift apart further and the LRS can no longer be RESET to HRS and the HRS can no longer be SET to LRS.

The step current generator 370 (FIG. 4) can generate a small temperature invariant current that can be injected to shift the boundary of the RESET curve 1202 and SET curve 1204, such that the IR0 at RH 1206 and IR1 at RL 1208 can be shifted within a range represented by broken lines 1214 for the IR0 boundary current and shifted within a range represented by broken lines 1216 for the IR0 boundary current. Thus, the step current generator 370, can generate a small current difference for the write verify level to achieve step-by-step boundary trimming. The injection of the current is controlled by the switches 346 to 352 and the switches 356 to 362, as described above. In some examples, the step-by-step boundary trimming and tailing bit can be SET/RESET with proposed write bias and thus avoid issues with over-SET/RESET.

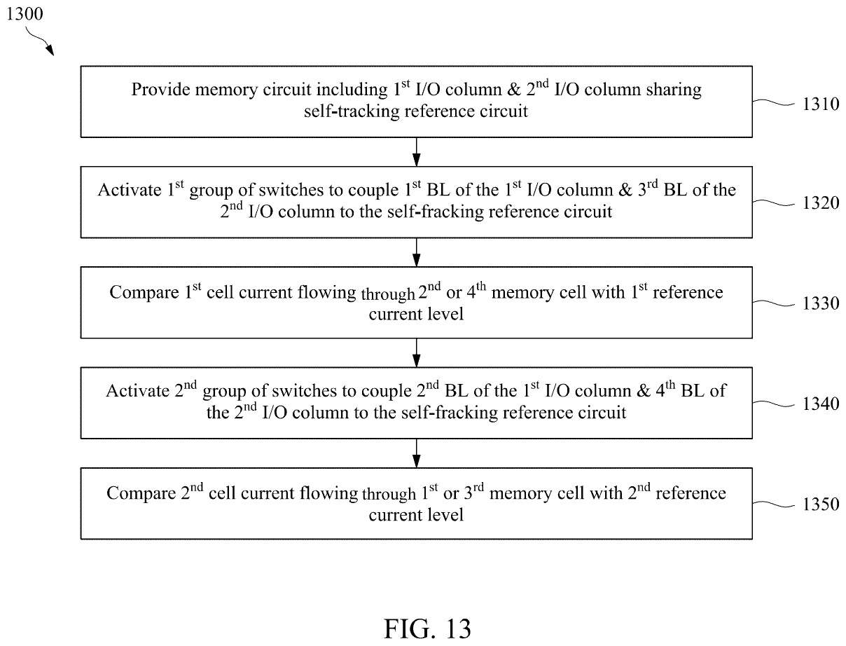

FIG. 13 illustrates a flow chart of an example method 1300 configured for operating a memory circuit, in accordance with some embodiments. For example, operations of the method 1300 can be utilized to operate the memory circuit 100 (e.g., FIG. 4) that includes the self-tracking reference circuit 150 operatively shared by multiple I/O columns. The following discussion of the method 1300 may thus be referred to the foregoing components. It is noted that the method 1300 is merely an example, and is not intended to limit the scope of the present disclosure. Accordingly, it should be understood that additional operations may be provided before, during, and/or after the method 1300 of FIG. 13, and that some other operations may only be briefly described herein.

The method 1300 starts with operation 1310 of providing a memory circuit including a first I/O column and a second I/O column operatively sharing a self-tracking reference circuit. In some embodiments, the first I/O column includes a first sense amplifier coupled to a first memory cell and a second memory cell through a first bit line and a second bit line, respectively, and the second I/O column includes a second sense amplifier coupled to a third memory cell and a fourth memory cell through a third bit line and a fourth bit line, respectively. The self-tracking reference circuit is coupled to the first bit line (of the first I/O column) and the third bit line (of the second I/O column) through activating a first group of switches and deactivating a second group of switches, and coupled to the second bit line (of the first I/O column) and the fourth bit line (of the second I/O column) through activating the second group of switches and deactivating the first group of switches.

Using the circuit implementation shown in FIG. 4 as a representative example, the self-tracking reference circuit 150 is shared by the I/O[0] and I/O[1], which include the sense amplifier 310 and the sense amplifier 320, respectively. The self-tracking reference circuit 150 can be coupled to the BL_L[0] and BL_L[1] while being decupled from the BL_R[0] or BL_R[1], through activation of the switches 346 to 352 and deactivation of the switches 356 to 362; and the self-tracking reference circuit 150 can be coupled to the BL_R[0] and BL_R[1] while being decupled from the BL_L[0] or BL_L[1], through deactivation of the switches 346 to 352 and activation of the switches 356 to 362. In some embodiments, the self-tracking reference circuit 150 can include the configurable resistor network 330 and the replica selector array 340, collectively configured to provide a plurality of reference current levels. For example, at least a SET verify level, a RESET verify level, and a normal read level can be provided by the self-tracking reference circuit 150.

The method 1300 continues to operation 1320 of activating the first group of switches to couple the first bit line and the third bit line to the self-tracking reference circuit, while deactivating the second group of switches to decouple the second bit line and the fourth bit line each from the self-tracking reference circuit. Continuing with the above example, the switches 346 to 352 can be activated and the switches 356 to 362 can be deactivated, such as to couple the self-tracking reference circuit 150 to the BL_L[0] and BL_L[1]. In some embodiments, the transistor 376 connected to the BL_L[0] and the similar transistor connecting the memory cell 115_L[1] to the BL_L[1] may be turned off, concurrently with the activation of the switches 346 to 352 and the deactivation of the switches 356 to 362. As a result, the self-tracking reference circuit 150 can provide a first reference current level for each of the sense amplifier 310 and the sense amplifier 320. The first reference current level can be adjusted according to an operation mode (e.g., a normal read operation, a SET verification operation, a RESET verification operation) of the memory cells 115_R[0] and 115_R[1].

The method 1300 continues to operation 1330 of comparing a first cell current flowing through the second or fourth memory cell with a first one of the plurality of reference current levels. Continuing with the above example, upon activating the switches 346 to 352 and deactivating the switches 356 to 362, the sense amplifier 310 can compare the cell current flowing through the memory cell 115_R[0] with the first reference current level, and/or the sense amplifier 320 can compare the cell current flowing through the memory cell 115_R[1] with the first reference current level. Based on the comparison, the sense amplifier 310 can, for example, determine or otherwise identify a data value programmed into the memory cell 115_R[0], and the sense amplifier 320 can, for example, determine or otherwise identify a data value programmed into the memory cell 115_R[1].

The method 1300 continues to operation 1340 of activating the second group of switches to couple the second bit line and the fourth bit line to the self-tracking reference circuit, while deactivating the first group of switches to decouple the first bit line and the third bit line each from the self-tracking reference circuit. Continuing with the above example, the switches 356 to 362 can be activated and the switches 346 to 352 can be deactivated, such as to couple the self-tracking reference circuit 150 to the BL_R[0] and BL_R[1]. In some embodiments, the transistor 378 connected to the BL_R[0] and the similar transistor connecting the memory cell 115_R[1] to BL_R[1] may be turned off, concurrently with the activation of the switches 356 to 362 and the deactivation of the switches 346 to 352. As a result, the self-tracking reference circuit 150 can provide a second reference current level for each of the sense amplifier 310 and the sense amplifier 320. The second reference current level can be adjusted according to an operation mode (e.g., a normal read operation, a SET verification operation, a RESET verification operation) of the memory cells 115_L[0] and 115_L[1].

The method 1300 continues to operation 1350 of comparing a second cell current flowing through the first or third memory cell with a second one of the plurality of reference current levels. Continuing with the above example, upon activating the switches 356 to 362 and deactivating the switches 346 to 352, the sense amplifier 310 can compare the cell current flowing through the memory cell 115_L[0] with the second reference current level, and/or the sense amplifier 320 can compare the cell current flowing through the memory cell 115_L[1] with the second reference current level. Based on the comparison, the sense amplifier 310 can, for example, determine or otherwise identify a data value programmed into the memory cell 115_L[0], and the sense amplifier 320 can, for example, determine or otherwise identify a data value programmed into the memory cell 115_L[1].

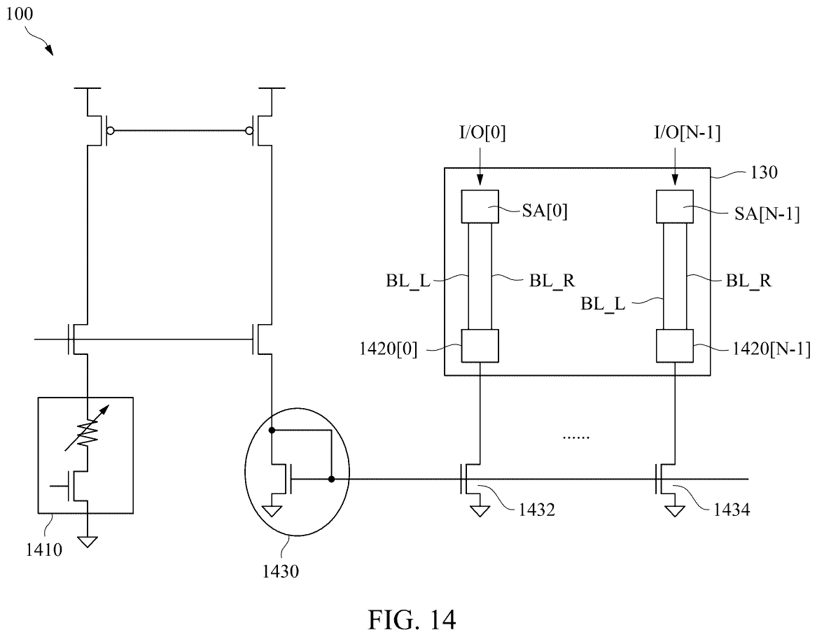

FIG. 14 illustrates another example schematic diagram of a portion of the memory circuit 100, in accordance with some embodiments of the present disclosure. The circuit diagram of FIG. 14 is similar to that of FIG. 3, except that the circuit diagram of FIG. 14 includes a global self-tracking reference circuit and multiple local self-tracking reference circuits corresponding to different I/O columns, respectively. It should be understood that the schematic diagram of FIG. 14 is provided merely for illustrative purposes, and does not intend to limit the scope of the present disclosure. Thus, the schematic diagram of FIG. 14 can include any of various other components, while remaining within the scope of the present disclosure.

As shown, in FIG. 14, the memory circuit 100 includes a global self-tracking reference circuit 1410 and multiple local self-tracking reference circuits 1420[0] to 1420[N−1]. The local self-tracking reference circuits 1420[0] to 1420[N−1] operatively correspond to I/O columns I/O[0] to I/O[N−1] of the I/O circuit 130, respectively, for example, each of the local self-tracking reference circuits 1420[0] to 1420[N−1] being coupled to a corresponding one of sense amplifiers (e.g., SA[0] to SA[N−1]) through a pair of bit lines (e.g., BL_L and BL_R). Similar to the self-tracking reference circuit 150 discussed above (including, e.g., 1100 of FIG. 11), the global self-tracking reference circuit 1410 and the local self-tracking reference circuits 1420[0] to 1420[N−1] are each configured to provide a plural number of reference levels (I_{ref}'s), based on the operation mode of a corresponding memory cell.

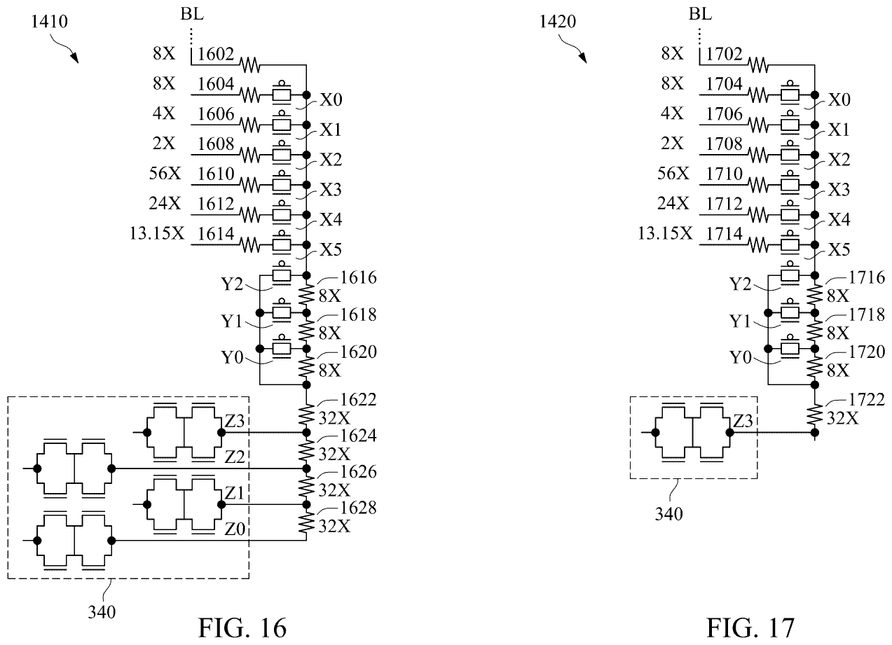

However, as will be discussed further in FIG. 16, the global self-tracking reference circuit 1410 is configured to provide a relatively wide range of reference levels, while the local self-tracking reference circuits 1420[0] to 1420[N−1] are each configured to provide a relatively narrow range of reference levels. In some embodiments, each of the I/O columns I/O[0] to I/O[N−1] can be coupled to a corresponding one of transistors, e.g., 1432 . . . 1434. The transistor 1432 can be operatively coupled to the I/O[0](or its local self-tracking reference circuit 1420), the transistor 1434 can be operatively coupled to the I/O[N−1](or its local self-tracking reference circuit 1420), and so on. The global self-tracking reference circuit 1410 can utilize transistors 1430, 1432 . . . 1434, which serve as a current mirror, to provide the reference level (selected from the wider range of reference levels) to the local self-tracking reference circuit 1420, as needed. For example, when the memory cell coupled to the I/O[0] operates under a mode that requires a reference level beyond the range that the local self-tracking reference circuit 1420[0] can provide, the global self-tracking reference circuit 1410 can provide such a reference level mirrored to the I/O[0] through the transistors 1430 and 1432.

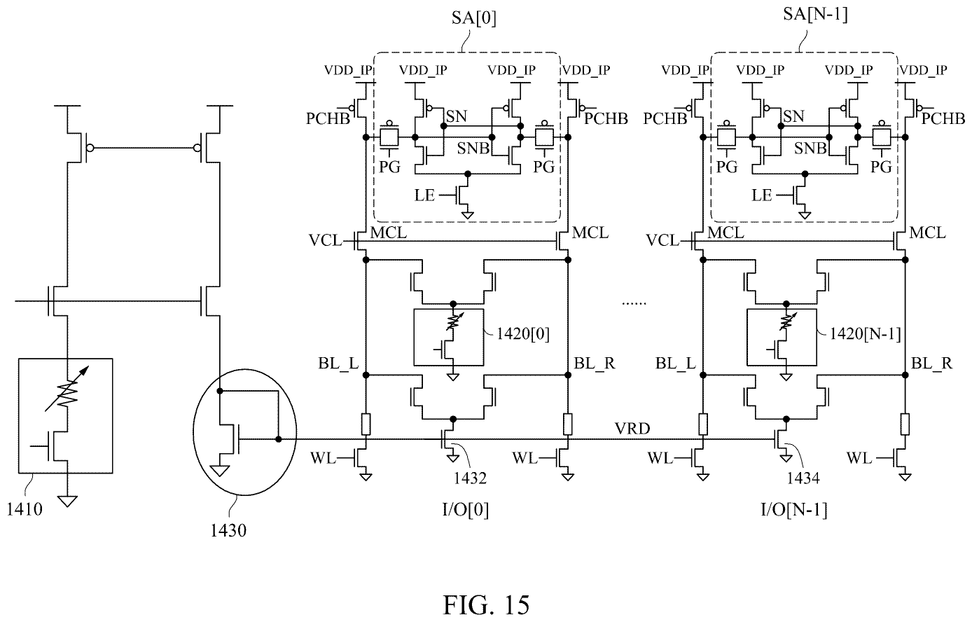

FIG. 15 illustrates an example circuit diagram of a portion of the memory circuit 100, configured based on the schematic diagram of FIG. 14, in accordance with some embodiments of the present disclosure. It should be understood that the circuit diagram of FIG. 15 is provided merely for illustrative purposes, and does not intend to limit the scope of the present disclosure.

As shown, each I/O column (e.g., I/O[0]) includes a sense amplifier (e.g., SA[0]) and a local self-tracking reference circuit (e.g., 1420[0]). The local self-tracking reference circuit 1420[0] can be coupled to the sense amplifier SA[0] through a pair of bit lines, BL_L and BL_R, that are coupled to respective memory cells. Further, each I/O column (e.g., I/O[0]) includes a transistor (e.g., 1432), together with the transistor 1430, that operatively serve as a current mirror.

FIG. 16 and FIG. 17 illustrate example circuit diagrams of the global self-tracking reference circuit 1410 and the local self-tracking reference circuit 1420, respectively, in accordance with some embodiments. As shown, the global self-tracking reference circuit 1410 and the local self-tracking reference circuit 1420 are each implemented similarly to the circuit diagram of FIG. 11, and thus, the following discussion of the circuit implementations of the global self-tracking reference circuit 1410 and the local self-tracking reference circuit 1420 will be focused on the difference.

In FIG. 16, the global self-tracking reference circuit 1410 includes a configurable resistor network substantially similar to the configurable resistor network 1100. For example, the configurable resistor network of the global self-tracking reference circuit 1410 includes resistors 1602 to 1612 coupled to switches X0 to X5 in parallel, and resistors 1616 to 1620 coupled to switches Y2 to Y0 in series, and resistors 1622 to 1628, and further, the configurable resistor network is coupled to the replica selector array 340 implemented as four transistor arrays. As discussed above, the global self-tracking reference circuit 1410 can thus provide a plural number (e.g., 128) of difference reference levels.

In FIG. 17, the local self-tracking reference circuit 1420 includes a configurable resistor network substantially similar to the configurable resistor network 1100, except that the configurable resistor network of the local self-tracking reference circuit 1420 includes a less number of resistors and the replica selector array 340 of the local self-tracking reference circuit 1420 includes a less number of transistor arrays. For example, the configurable resistor network of the local self-tracking reference circuit 1420 includes resistors 1702 to 1672 coupled to switches X0 to X5 in parallel, and resistors 1716 to 1720 coupled to switches Y2 to Y0 in series, and resistor 1722, and further, the configurable resistor network is coupled to the replica selector array 340 implemented as one transistor array. As discussed above, the local self-tracking reference circuit 1420 can thus provide a plural number (e.g., 32) of difference reference levels.

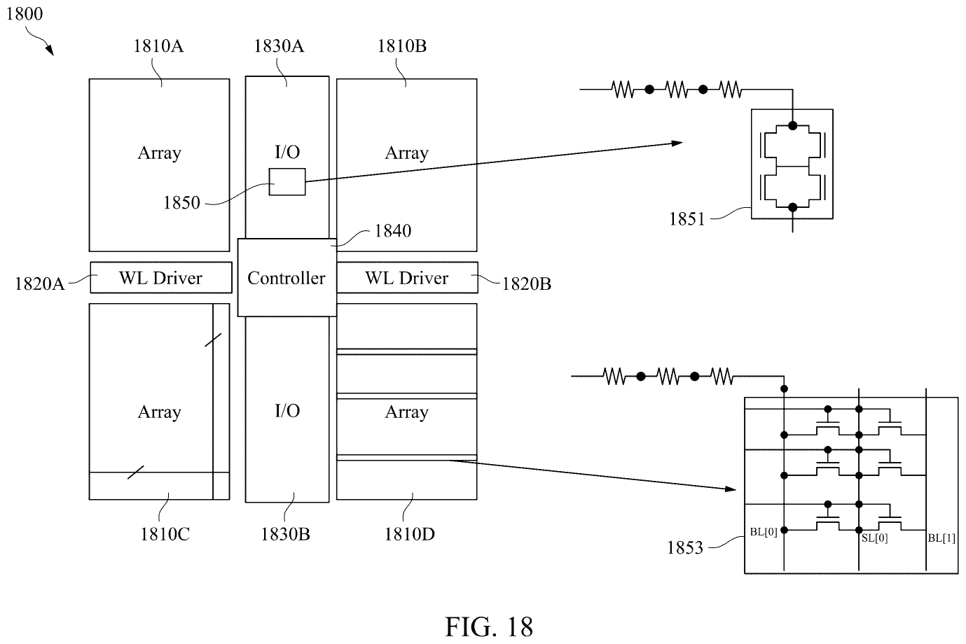

FIG. 18 illustrates an example block diagram of a memory circuit 1800, in accordance with some embodiments. The memory circuit 1800 is substantially similar to the block diagram of memory circuit 100 shown in FIG. 1, except that the memory circuit 1800 may include four memory arrays 1810A, 1810B, 1810C, and 1810D. Each of the memory arrays 1810A to 1810D includes a plural number of bit lines BLs extending in a first direction and a plural number of word lines WLs extending in a second, perpendicular direction. These memory arrays 1810A to 1810D may operatively share one memory controller 1840, two I/O circuits 1830A and 1830B, and two WL drivers 1820A and 1820B.

In some embodiments, the memory arrays 1810A, 1810B, 1810C, and 1810D may be physically disposed around four corners, respectively. The I/O circuit 1830A can be physically interposed between the memory arrays 1810A and 1810B, and the I/O circuit 1830B can be physically interposed between the memory arrays 1810C and 1810D. Accordingly, the memory arrays 1810A and 1810B (or their respective memory cells) can be operatively coupled to the I/O circuit 1830A through their respective bit lines BLs, and the memory arrays 1810C and 1810D (or their respective memory cells) can be operatively coupled to the I/O circuit 1830B through their respective bit lines BLs. The WL driver 1820A can be physically interposed between the memory arrays 1810A and 1810C, and the WL driver 1820B can be physically interposed between the memory arrays 1810B and 1810D. Accordingly, the memory arrays 1810A and 1810C (or their respective memory cells) can be operatively coupled to the WL driver 1820A through their respective word lines WLs, and the memory arrays 1810B and 1810D (or their respective memory cells) can be operatively coupled to the WL driver 1820B through their respective word lines WLs.

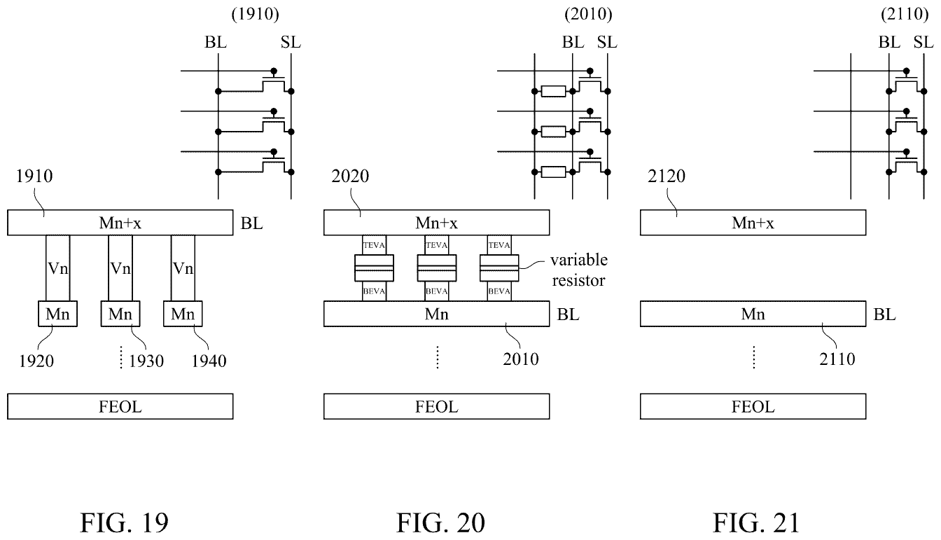

At least one of the I/O circuit 1830A or I/O circuit 1830B can include a self-tracking reference circuit 1850 formed of a configurable resistor network and a replica selector array, similar to the above-discussed self-tracking reference circuit 150. In one aspect, the replica selector array (e.g., 1851) of the self-tracking reference circuit 1850 may be formed in the same physical region as the I/O circuit (e.g., 1830A). For example, transistors operatively forming sense amplifiers of the I/O circuit 1830A and transistors operatively forming the replica selector array 1851 may be formed in the same physical region. In another aspect, the replica selector array (e.g., 1853) of the self-tracking reference circuit 1850 may be formed in the same physical region as one of the memory arrays (e.g., 1810D). For example, the memory array 1810D can include one or more nominal columns re-enlisted as dummy columns to form the replica selector array, which will be described further in FIGS. 19-21.

In each of FIG. 19-21, over the FEOL network (e.g., transistors), a number of metallization layers (e.g., Mₙ, Mₙ₊ₓ) can be formed, ‘x” can be any integer equal to or greater than 1. When x=1, Mₙ and Mₙ₊₁ may be vertically adjacent to each other. When x+2, Mₙ and Mₙ₊₂ may be vertically disposed with respect to each other, with another metallization layer interposed therebetween. Each of the metallization layers can include a number of metal tracks. In some embodiments, the metal track of one of the metallization layers can operatively serve as a bit line BL of one of the dummy columns, and the bit line BL can be electrically coupled to the transistors in the FEOL network without effective variable resistor being formed.

For example, in FIG. 19, metal track 1910 in the Mₙ₊ₓ layer, serving as the bit line BL, can be electrically connected to different metal tracks 1920, 1930, and 1940 in the Mₙ layer through respective via structures Vₙ's. An equivalent circuit diagram including three transistors formed in the FEOL network with their first source/drain terminals directly electrically connected to the bit line BL (i.e., without variable resistors) is also illustrated in FIG. 19. In FIG. 20, metal track 2010 in the Mₙ layer, serving as the bit line BL, can be electrically connected to metal track 2020 in the Mₙ₊ₓ layer through a number of bottom electrode vias BEVA's, variable resistors, and top electrode vias TEVA's. These variable resistors are not formed, in some embodiments. An equivalent circuit diagram including three transistors formed in the FEOL network with their first source/drain terminals directly electrically connected to the bit line BL (i.e., without variable resistors formed therebetween) is also illustrated in FIG. 20. In FIG. 21, metal track 2110 in the Mₙ layer, serving as the bit line BL, can be electrically disconnected from metal track 2120 in the Mₙ₊ₓ layer. An equivalent circuit diagram including three transistors formed in the FEOL network with their first source/drain terminals directly electrically connected to the bit line BL (i.e., without variable resistors formed therebetween) is also illustrated in FIG. 21. It should be appreciated that second source/drain terminals of those transistors are electrically connected to at least another metal track serving as a source line SL (not shown in FIGS. 19-21).

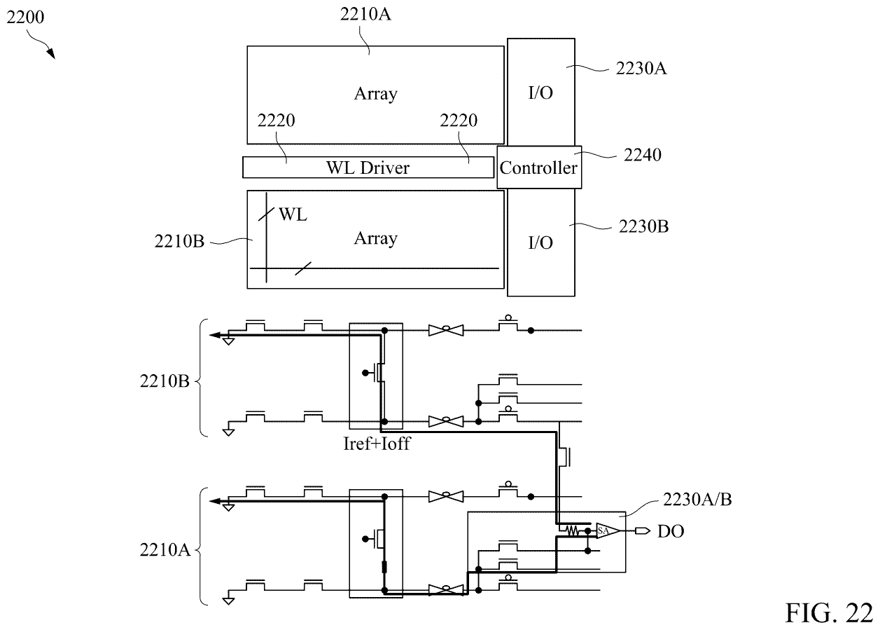

FIG. 22 illustrates an example block diagram of a memory circuit 2200, in accordance with some embodiments. The memory circuit 2200 is substantially similar to the block diagram of memory circuit 1800 shown in FIG. 18, except that the memory circuit 2200 may include a less number of memory arrays, e.g., 2210A and 2210B. Each of the memory arrays 2210A and 2210B includes a plural number of bit lines BLs extending in a first direction and a plural number of word lines WLs extending in a second, perpendicular direction. These memory arrays 2210A and 2210B may operatively share one memory controller 2240, two I/O circuits 2230A and 2230B, and one WL driver 2220. In some embodiments, one of the memory arrays (e.g., 2210B) can include one or more columns re-enlisted as dummy columns for forming the replica selector array of a self-tracking reference circuit, as discussed with respect to FIGS. 18-21. By configuring the self-tracking reference circuit as such (with its replica selector array formed along the dummy columns of memory array 2210B), a tracking read leakage current (I_{off}) can be provided by the same memory array (e.g., 2210B) to compensate the reference level (I_{ref}).

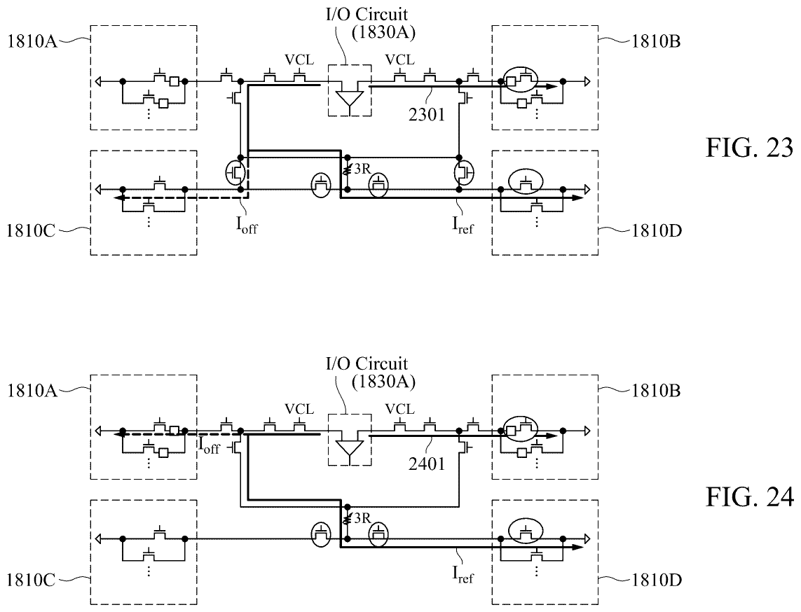

FIG. 23 and FIG. 24 illustrate two example circuit diagrams configured based on the block diagram of FIG. 18, in accordance with some embodiments. For example, in FIG. 23, the I/O circuit 1830A (or its sense amplifier) can compare a cell current 2301 read from the memory array 1810B with a reference level (I_{ref}) generated by the self-tracking reference circuit formed along one or more dummy columns of the memory array 1810D, where the reference level is compensated with a tracking read leakage current (I_{off}) generated from one or more dummy columns of the memory array 1810C. In FIG. 24, the I/O circuit 1830A (or its sense amplifier) can compare a cell current 2401 read from the memory array 1810B with a reference level (I_{ref}) generated by the self-tracking reference circuit formed along one or more dummy columns of the memory array 1810D, where the reference level is compensated with a tracking read leakage current (I_{off}) generated from one or more dummy columns of the memory array 1810A.

In one aspect of the present disclosure, a memory circuit is disclosed. The memory circuit includes a first memory cell and a second memory cell coupled to a first sense amplifier through a first bit line and a second bit line, respectively; a third memory cell and a fourth memory cell coupled to a second sense amplifier through a third bit line and a fourth bit line, respectively; a reference circuit configured to provide a plurality of reference current levels corresponding to different operation modes of any of the first to fourth memory cells, respectively. The reference circuit is alternately coupled to the first bit line and the third bit line or coupled to second bit line and the fourth bit line.

In another aspect of the present disclosure, a memory circuit is disclosed. The memory circuit includes a first memory cell and a second memory cell coupled to a first sense amplifier through a first bit line and a second bit line, respectively; a third memory cell and a fourth memory cell coupled to a second sense amplifier through a third bit line and a fourth bit line, respectively, wherein the first to fourth memory cells are each configured to present a first resistance state or a second resistance state; and a reference circuit configured to provide a plurality of reference current levels for both of the first and second sense amplifiers.

In yet another aspect of the present disclosure, a method for operating memory circuits is disclosed. The method includes activating a first group of switches to couple a first bit line and a second bit line to a reference circuit, while deactivating a second group of switches, so as to decouple a third bit line and a fourth bit line each from the reference circuit, wherein the reference circuit is configured to provide a plurality of reference current levels. The method includes comparing a first cell current flowing through a first one of a plurality of memory cells with a first one of the plurality of reference current levels, wherein the first memory cell is coupled to a first sense amplifier through the third bit line or the fourth bit line. The method includes deactivating the first group of switches to decouple the first bit line and the second bit line each from the reference circuit, while activating the second group of switches to couple the third bit line and the fourth bit line to the reference circuit. The method includes comparing a second cell current flowing through a second one of the plurality of memory cells with a second of the plurality of reference current levels, wherein the second memory cell is coupled to a second sense amplifier through the first bit line or the second bit line.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory circuit, comprising:
a first memory cell and a second memory cell coupled to a first sense amplifier through a first bit line and a second bit line, respectively;
a third memory cell and a fourth memory cell coupled to a second sense amplifier through a third bit line and a fourth bit line, respectively; and
a reference circuit configured to provide a plurality of reference current levels corresponding to different operation modes of any of the first to fourth memory cells, respectively;
wherein the reference circuit is alternately coupled to the first bit line and the third bit line or coupled to the second bit line and the fourth bit line.

2. The memory circuit of claim 1, wherein each of the first to fourth memory cells includes a resistive random access memory (RRAM) cell.

3. The memory circuit of claim 1, wherein the reference circuit includes a first resistor, a second resistor, a third resistor, and a transistor array connected in series.

4. The memory circuit of claim 3, wherein the transistor array includes one transistor, four transistors, nine transistors, or sixteen transistors.

5. The memory circuit of claim 1, further comprising:
a first switch selectively coupled between the first bit line and the third bit line;
a second switch selectively coupled between the first bit line and a first transistor switch connected to the reference circuit;
a third switch selectively coupled between the third bit line and the first transistor switch connected to the reference circuit;
a fourth switch selectively coupled between the second bit line and the fourth bit line;
a fifth switch selectively coupled between the second bit line and a second transistor switch connected to the reference circuit; and
a sixth switch coupled between the fourth bit line and the second transistor switch connected to the reference circuit.

6. The memory circuit of claim 5, wherein the first to third switches are configured to be activated, while the fourth to sixth switches are configured to be deactivated, causing the first sense amplifier to compare one of the plurality of reference current levels with a first cell current flowing through the second memory cell, or causing the second sense amplifier to compare the one of the plurality of reference current levels with a second cell current flowing through the fourth memory cell.

7. The memory circuit of claim 5, wherein the first to third switches are configured to be deactivated, while the fourth to sixth switches are configured to be activated, causing the first sense amplifier to compare one of the plurality of reference current levels with a first cell current flowing through the first memory cell, or causing the second sense amplifier to compare the one of the plurality of reference current levels with a second cell current flowing through the third memory cell.

8. The memory circuit of claim 1, further comprising:
a first switch selectively coupled between the first bit line and the third bit line;
a first transistor switch selectively coupled between the first bit line and a reference line;
a second transistor switch selectively coupled between the third bit line and the reference line;
a second switch selectively coupled between the second bit line and the fourth bit line;
a third transistor switch selectively coupled between the second bit line and the reference line; and
a fourth transistor switch coupled between the fourth bit line and the reference line.

9. The memory circuit of claim 8, wherein the reference line is coupled between the reference circuit and one source/drain terminal of each of the first to fourth transistor switches.

10. The memory circuit of claim 1, wherein the different operation modes include a normal read, a first write verification, and a second write verification of each of the first to fourth memory cells.

11. A memory circuit, comprising:
a first memory cell and a second memory cell coupled to a first sense amplifier through a first bit line and a second bit line, respectively;
a third memory cell and a fourth memory cell coupled to a second sense amplifier through a third bit line and a fourth bit line, respectively, wherein the first to fourth memory cells are each configured to present a first resistance state or a second resistance state; and
a reference circuit configured to provide a plurality of reference current levels for both of the first and second sense amplifiers.

12. The memory circuit of claim 11, wherein a first one of the plurality of reference current levels corresponds to reading any of the first to fourth memory cells, a second one of the plurality of reference current levels corresponds to verifying whether the first resistance state is written to any of the first to fourth memory cells, and a third one of the plurality of reference current levels corresponds to verifying whether the second resistance state is written to any of the first to fourth memory cells.

13. The memory circuit of claim 11, wherein the reference circuit includes a first resistor, a second resistor, a third resistor, and a transistor array connected in series.

14. The memory circuit of claim 13, wherein the transistor array includes one transistor, four transistors, nine transistors, or sixteen transistors.

15. The memory circuit of claim 11, further comprising:
a first switch selectively coupled between the first bit line and the third bit line;
a second switch selectively coupled between the first bit line and a first transistor switch connected to the reference circuit;
a third switch selectively coupled between the third bit line and the first transistor switch connected to the reference circuit;
a fourth switch selectively coupled between the second bit line and the fourth bit line;
a fifth switch selectively coupled between the second bit line and a second transistor switch connected to the reference circuit; and
a sixth switch coupled between the fourth bit line and the second transistor switch connected to the reference circuit.

16. The memory circuit of claim 15, wherein the first to third switches are activated, with the fourth to sixth switches deactivated, or the first to third switches are deactivated, with the fourth to sixth switches activated.

17. The memory circuit of claim 11, further comprising:
a first switch selectively coupled between the first bit line and the third bit line;
a first transistor switch selectively coupled between the first bit line and a reference line;
a second transistor switch selectively coupled between the third bit line and the reference line;
a second switch selectively coupled between the second bit line and the fourth bit line;
a third transistor switch selectively coupled between the second bit line and the reference line; and
a fourth transistor switch coupled between the fourth bit line and the reference line.

18. The memory circuit of claim 17, wherein the first switch, the first transistor switch, and the second transistor switch are activated, with the second switch, the third transistor switch, and the fourth transistor switch deactivated, or the first switch, the first transistor switch, and the second transistor switch are deactivated, with the second switch, the third transistor switch, and the fourth transistor switch activated.

19. A method for operating memory circuits, comprising:
activating a first group of switches to couple a first bit line and a second bit line to a reference circuit, while deactivating a second group of switches, so as to decouple a third bit line and a fourth bit line each from the reference circuit, wherein the reference circuit is configured to provide a plurality of reference current levels;
comparing a first cell current flowing through a first one of a plurality of memory cells with a first one of the plurality of reference current levels, wherein the first memory cell is coupled to a first sense amplifier through the third bit line or the fourth bit line;
deactivating the first group of switches to decouple the first bit line and the second bit line each from the reference circuit, while activating the second group of switches to couple the third bit line and the fourth bit line to the reference circuit; and
comparing a second cell current flowing through a second one of the plurality of memory cells with a second of the plurality of reference current levels, wherein the second memory cell is coupled to a second sense amplifier through the first bit line or the second bit line.

20. The method of claim 19, wherein the plurality of reference current levels correspond to different operation modes of any of the plurality of memory cells, respectively.
